(19) United States
(12) Patent Application Publication
(10) Pub. No.: US 2005/0224876 A1
(43) Pub. Date: Oct. 13, 2005

(54) [STRUCTURE OF LTPS-TFT AND METHOD OF FABRICATING CHANNEL LAYER THEREOF]

(76) Inventor: Cheng Chang Kuo, Taoyuan (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/710,729

(22) Filed: Jul. 30, 2004

(30) Foreign Application Priority Data
Apr. 5, 2004 (TW) 93109339

(51) Int. Cl. H01L 27/01

(52) U.S. Cl. 257/347

(57) ABSTRACT

A LTPS-TFT structure comprising a cap layer, a polysilicon film and a gate is provided. The cap layer is disposed over the substrate with a gap between the two. The polysilicon film is disposed over the cap layer and is divided into a channel region and a source/drain region on each side of the channel region. The channel region is located above the gap. The gate is disposed above the channel region. Because the gap lies underneath the channel region, the thermal conductivity in the channel region is lower during the laser annealing process. Therefore, the silicon atoms can have a longer re-crystallization time so that larger grains are formed within the channel region and grain boundary therein is reduced. Furthermore, the grain orientation of the polysilicon film is mostly parallel to the transmission direction of electron within the transistor so that the operation efficiency of the transistor is improved.

### CROSS REFERENCE TO RELATED APPLICATIONS

This application claims the priority benefit of Taiwan application serial no. 93109339, filed Apr. 5, 2004.

### BACKGROUND OF INVENTION

1. Field of the Invention

The present invention relates to a thin film transistor and method of fabricating a channel layer thereof. More particularly, the present invention relates to a low temperature polysilicon thin film transistor (LTPS-TFT) and method of fabricating a channel layer thereof.

2. Description of the Related Art

Most electronic devices require a switch for driving the device. For example, an active display device is often triggered using a thin film transistor (TFT). In general, thin film transistors can be further subdivided according to the channel material into amorphous silicon (a-Si) thin film transistor and polysilicon thin film transistor. Since the polysilicon thin film transistors have a lower power consumption rate and a larger electron migration rate than the amorphous silicon thin film transistors, polysilicon thin film transistors are more popular.

In the early days, the polysilicon thin film transistors are fabricated at a temperature up to 1000° C. so that possible choice of material for forming the substrate is severely limited. With the advent of laser techniques, the processing temperature has dropped to about 600° C. or lower. The polysilicon thin film transistors formed at a low temperature is now referred to as a low temperature polysilicon thin film transistor (LTPS-TFT).

To form an LTPS-TFT, an amorphous silicon film is formed over a substrate and then the amorphous silicon is melted and then re-crystallized into a polysilicon film. FIGS. 1A and 1B are schematic cross-sectional views showing the steps for fabricating a conventional LTPS-TFT. The most common laser annealing process is the so-called excimer laser annealing (ELA) process. After forming an amorphous silicon film 102 over the substrate 100, an excimer laser beam 106 is applied to melt the amorphous silicon film 102 in a laser annealing process as shown in FIG. 1A. Thereafter, the melt silicon film 102 is allowed to cool and re-crystallize into a polysilicon film 102a as shown in FIG. 1B.

However, the average grain size of the polysilicon film 102a is usually small and significant grain size variation is obtained after an ELA process. Therefore, the polysilicon film 102a has lots of grain boundaries so that the migration rate of electrons within the polysilicon channel is at most between 100 to 200 cm²/V-sec. With such a low electron migration rate, electrical performance of the thin film transistor will be significantly affected.

To improve the performance of an LTPS-TFT, another type of laser annealing process called the sequential lateral solidification (SLS) process has been developed. FIGS. 2A and 2B are schematic cross-sectional views showing the steps for fabricating another conventional LTPS-TFT. A photomask 104 is used to limit the extent of exposure by a laser beam 106 on the amorphous silicon film 102 as shown in FIG. 2A. After a period of time, the melted amorphous silicon film 102 (the amorphous film 102 within the area 110) utilizes the un-melt amorphous silicon film 102 in adjacent region as a nucleus for lateral crystal growth as shown in FIG. 2B. Therefore, a polysilicon film 202a is formed within the area 110.

As shown in FIG. 2B, the SLS process is capable of forming a polysilicon film 202a having a larger average grain size. In other words, the polysilicon film 202a formed by the SLS annealing process has fewer grain boundaries and hence a higher electron migration rate compared with one formed by the conventional ELA annealing process. Aside from providing the thin film transistor with a higher electrical performance, the SLS process also produces a polysilicon film having more uniform grain orientation.

However, more expensive equipment and an additional photomask compared with an ELA annealing process is required to perform the SLS annealing operation. Hence, the cost of producing the transistor is higher. In addition, the SLS process demands a longer time to complete the fabrication of the polysilicon film.

### SUMMARY OF INVENTION

Accordingly, at least one objective of the present invention is to provide a low temperature polysilicon thin film transistor (LTPS-TFT) structure having a channel having uniform grain size and fewer grain boundaries so that the transistor can have better electrical performance.

At least a second objective of the present invention is to provide a method of fabricating the channel layer of a LTPS-TFT such that the grain size and grain orientation of the channel layer can be adjusted to increase the migration rate of electrons through the channel layer. In addition, the LTPS-TFT can be fabricated using conventional production equipment to reduce overall production cost.

To achieve these and other advantages and in accordance with the purpose of the invention, as embodied and broadly described herein, the invention provides a low temperature polysilicon thin film transistor (LTPS-TFT) on a substrate. The LTPS-TFT mainly comprises a cap layer, a polysilicon film and a gate. The cap layer is disposed over the substrate with a gap between the cap layer and the substrate. The polysilicon film is disposed over the cap layer. The polysilicon film can be divided into a channel region and a source/drain region on each side of the channel region. The channel region is above the gap and the channel region of the polysilicon film is the channel layer of the transistor. The gate is disposed over the channel region.

According to one embodiment of the present invention, the LTPS-TST structure further comprises a buffer layer over the substrate. The buffer layer is disposed between the cap layer and the substrate for preventing unexpected dopant diffusion from the substrate to affect device performance. In the present embodiment, the gap is located between the cap layer and the buffer layer, for example. Furthermore, the gap has a coefficient of thermal conductivity lower than the buffer layer and the substrate.

According to one embodiment of the present invention, the LTPS-TFT structure further includes a gate dielectric layer disposed over the polysilicon film.

According to one embodiment of the present invention, the channel region of the polysilicon film has an average grain size larger than the source/drain region of the polysilicon film. Hence, the transistor has a higher driving current and a lower leakage current. Furthermore, because the grain size on average of the channel region of the polysilicon film is larger, the total quantity of grain boundary within the channel region is less than that within the source/drain region. Since electrons moving inside the channel region when driven by an electric field will be less readily dispersed by grain boundaries, the migration rate of electrons inside the channel region is increased. In addition, the gate has a width preferably smaller than the grain size of the channel region. In another embodiment, the gate can have a dual gate structure, for example. With a dual gate structure, the electrons are less affected by the grain boundary in the middle of the channel. Ultimately, the electrical performance of the transistor is improved substantially.

According to one embodiment of the present invention, the low temperature polysilicon transistor structure further comprises a dielectric layer and a source/drain conductive layer. The dielectric layer is disposed over the polysilicon film to cover the gate. A source/drain contact window is formed in the dielectric layer and the gate dielectric layer and exposes the source/drain region. The source/drain conductive layer is disposed over the dielectric layer and is electrically connected to the source/drain region through the source/drain contact window.

The present invention also provides a method of fabricating the channel layer of a low temperature polysilicon transistor structure. First, a sacrificial layer is formed over the substrate. Next, a cap layer and an amorphous silicon film are sequentially formed over the sacrificial layer. Thereafter, the sacrificial layer is removed to form a gap between the substrate and the cap layer. The amorphous silicon film is melted and then re-crystallized to form a polysilicon channel on the cap layer above the gap.

According to one embodiment of the present invention, the method further comprises forming a buffer layer over the substrate before forming the sacrificial layer such that the buffer layer can serve as a barrier to an unexpected diffusion of dopants from the substrate. This is followed by the formation of a sacrificial layer over the buffer layer.

According to one embodiment of the present invention, the method of removing the sacrificial layer includes performing a wet etching operation. For example, the substrate with the structure thereon is immersed in an etching solution. In this step, the etching solution has a much higher etching rate for the sacrificial layer than the other film layers on the substrate.

According to the embodiment of the present invention, the method of melting the amorphous silicon film and then allowing melt silicon to re-crystallize includes aiming an excimer laser beam at the amorphous silicon film to change the amorphous silicon into a liquid state. Thereafter, an annealing process is carried out so that grains within the silicon material are re-crystallized to form a polysilicon film. The polysilicon film above the gap is the polysilicon channel layer of the transistor. Moreover, the grain size of the polysilicon channel is on average larger than the grain size of the polysilicon channel in other areas.

The grain orientation of the polysilicon film formed according to the present invention is parallel to the direction of transmission of the electrons within the transistor during operation. Hence, the electron migration rate within the channel region is increased and the electrical performance of the transistor is improved.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention.

FIGS. 1A and 1B are schematic cross-sectional views showing the steps for fabricating a conventional LTPS-TFT.

FIGS. 2A and 2B are schematic cross-sectional views showing the steps for fabricating another conventional LTPS-TFT.

FIG. 3 is a schematic cross-sectional view of an LTPS-TFT according to one preferred embodiment of the present invention.

FIG. 4A is a top view of the LTPS-TFT according to the embodiment of the present invention.

FIG. 4B is a top view of the LTPS-TFT according to another embodiment of the present invention.

FIGS. 5A through 5E are schematic cross-sectional views showing the steps for fabricating the channel of a LTPS-TFT according to one preferred embodiment of the present invention.

FIGS. 6A, 6B, 6C and 6E are the top views of FIGS. 5A, 5B, 5C and 5E respectively.

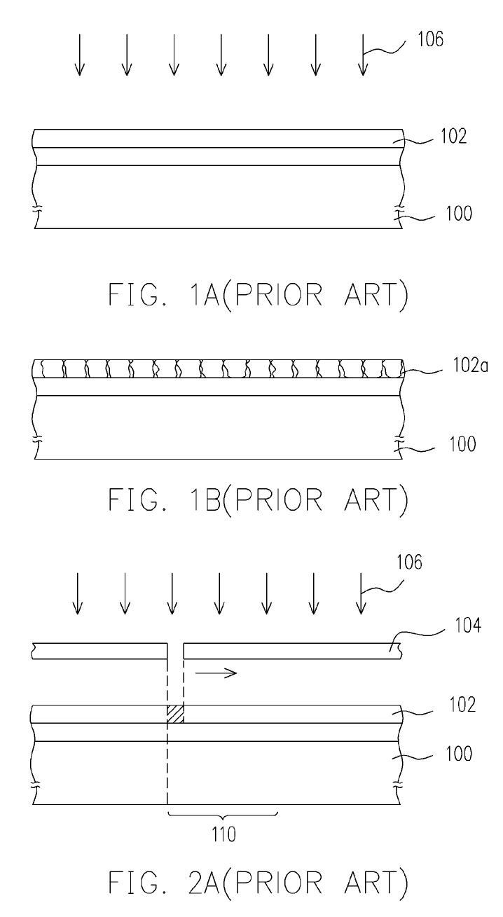

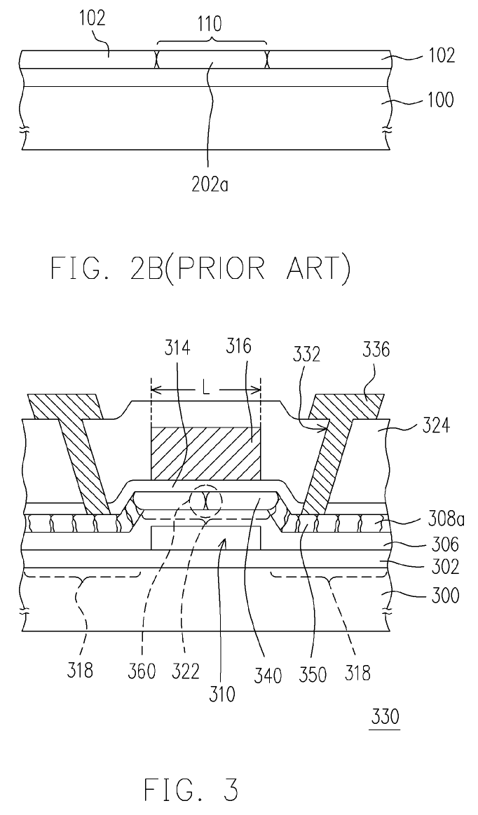

### DETAILED DESCRIPTION

Reference will now be made in detail to the present preferred embodiments of the invention, examples of which are illustrated in the accompanying drawings. Wherever possible, the same reference numbers are used in the drawings and the description to refer to the same or like parts.

Before carrying out the operation of converting the amorphous silicon into a polysilicon film, the sacrificial layer underneath the polysilicon channel is removed to form a gap having a thermal conductivity lower than each end of the gap. In this way, the re-crystallization rate of silicon above the gap is slower than the side regions so that the grain will grow from each side towards the center. In other words, the grains near the mid-section of the channel region will be larger. In the following, the principle ideas behind the present invention are described. However, it should by no means limit the scope of the present invention.

FIG. 3 is a schematic cross-sectional view of an LTPS-TFT according to one preferred embodiment of the present invention. As shown in FIG. 3, the low temperature polysilicon thin film transistor 330 (LTPS-TFT) mainly comprises a substrate 300, a cap layer 306, a polysilicon film 308a, a gate 316 and a source/drain conductive layer 336. The cap layer 306 is disposed above the substrate 300. In the present embodiment, a buffer layer 302 is sandwiched between the cap layer 306 and the substrate 300 to prevent an unexpected diffusion of the dopants within the substrate 300 into other areas and affect the performance of the device.

Furthermore, a gap 310 is formed between the cap layer 306 and the buffer layer 302, for example. The gap 310 contains a material having a low coefficient of thermal conductivity such as air or other types of gases, for example.

The polysilicon film 308a is disposed on the cap layer 306. The polysilicon film 308a can be divided into a channel region 322 and a doped source/drain region 318. The channel region 322 is located above the gap 310 and the channel region 322 of the polysilicon film 308a is the polysilicon channel layer of the LTPS-TFT 330. The gate 316 is disposed above the channel region 322 of the polysilicon film 308a. In addition, a gate dielectric layer 314 is disposed on the polysilicon film 308a too.

A dielectric layer 324 is disposed on the gate dielectric layer 314 to cover the gate 316. The source/drain conductive layer 336 is disposed on the dielectric layer 324.

The source/drain conductive layer 336 is electrically connected to the source/drain region 318 through a source/drain contact window 332 formed in the dielectric layer 324 and the gate dielectric layer 314.

It should be note that the grains 340 within the channel region 322 of the polysilicon film 308a have an average grain size greater than the grains 350 within the source/drain region 318 of the polysilicon film 308a. Preferably, the grains 340 may have a grain size slightly greater than half the length L of the channel region 322. Hence, the LTPS-TFT 330 can have a higher driving current. Furthermore, because the grain size of grains 340 within the channel region 322 is larger, total grain boundary 360 inside the channel region 322 is less than the total grain boundary 360 inside the source/drain region 318. In addition, the grain orientation is parallel to the transmission direction of electrons inside the LTPS-TFT 330. Therefore, when the LTPS-TFT 330 is in an operating mode, electron (carriers) can easily pass through the channel region 322 with very little dispersion by grain boundary 360 inside the channel region 322. In other words, the electron migration rate is increased.

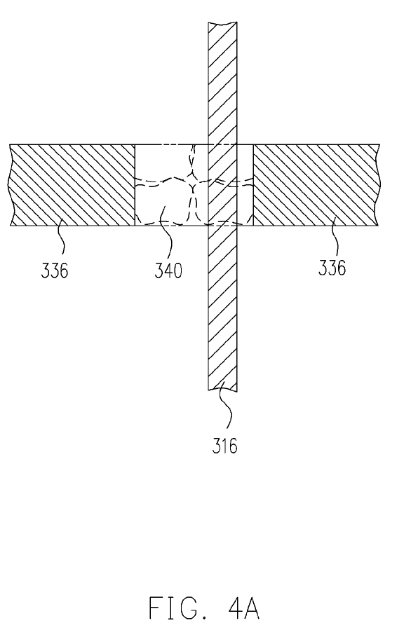

The present invention also permits a reduction of the width of the gate 316 within the LTPS-TFT 330 so that the width is smaller than the grain size of grains 340 (as shown in FIG. 4A). In this way, the channel region of the thin film transistor is prevented from crossing the grain boundary so that the thin film transistor can have a better performance. One skill artisan may notice that the so-called grain size refers to the length of grain in a direction parallel to the gate width.

Aside from reducing the width of the gate, a dual gate structure 416 may form on the LTPS-TFT as shown in FIG. 4B. FIG. 4B is a top view of the LTPS-TFT according to another embodiment of the present invention. With a dual gate structure 416, the effect of the grain boundary in the middle of the channel on the electrons is substantially reduced so that the transistor can have a much better performance.

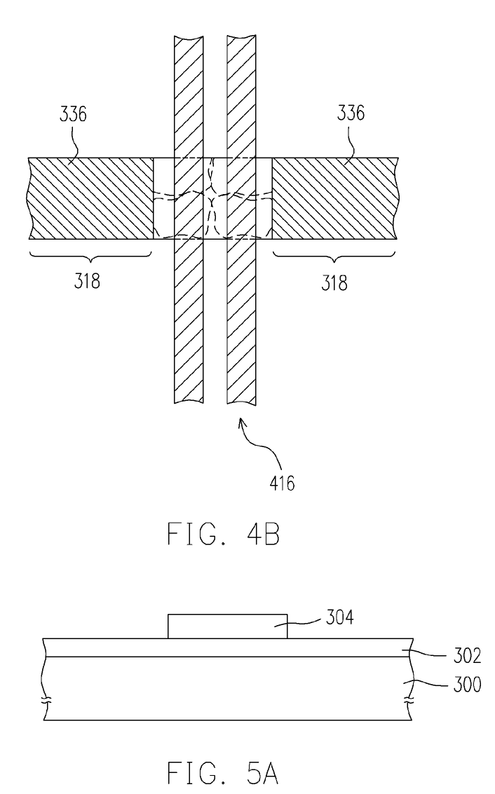

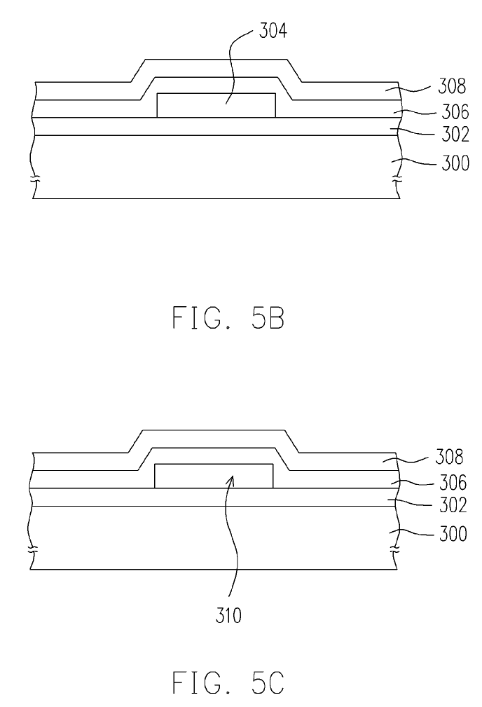

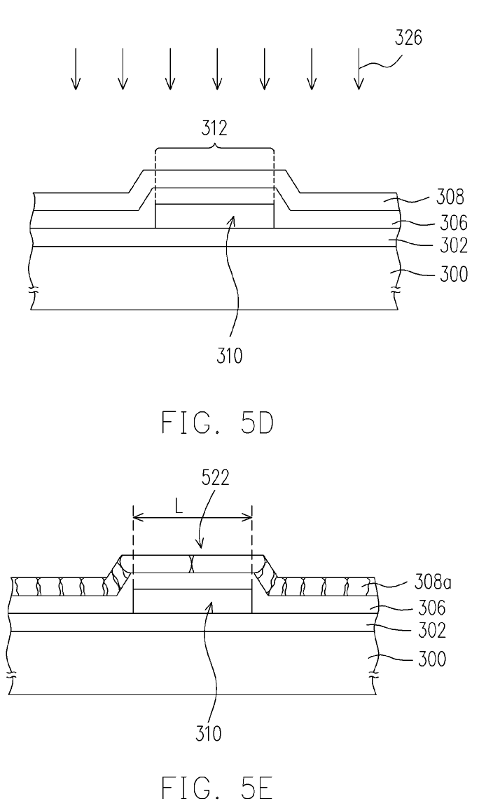

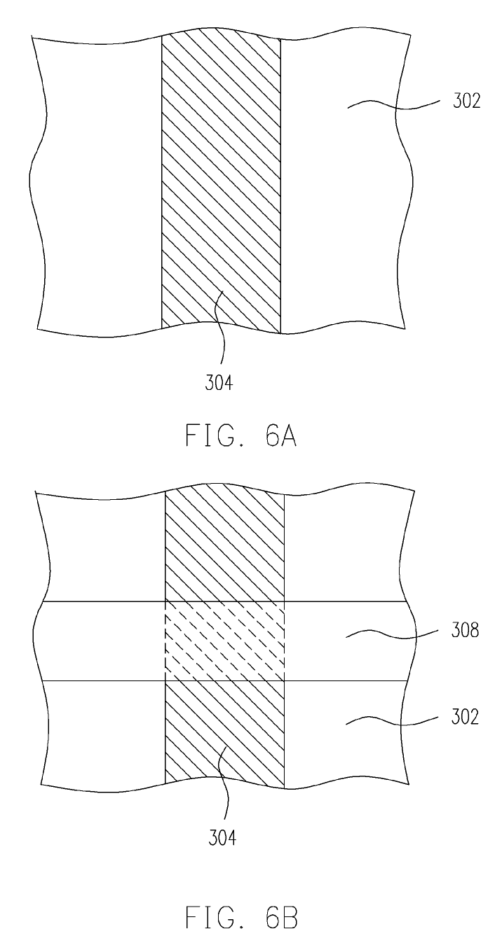

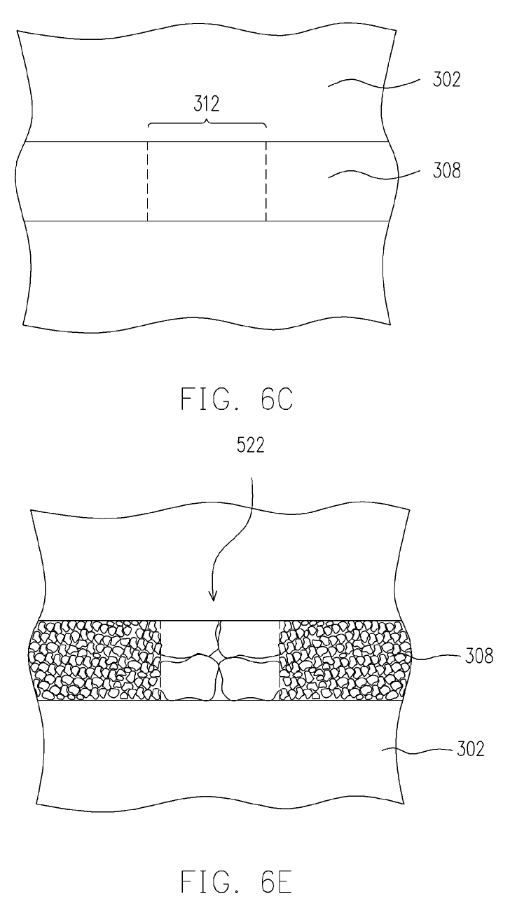

FIGS. 5A through 5E are schematic cross-sectional views showing the steps for fabricating the channel of a LTPS-TFT according to one preferred embodiment of the present invention. FIGS. 6A, 6B, 6C and 6E are the top views of FIGS. 5A, 5B, 5C and 5E respectively. First, as shown in FIG. 5A, a buffer layer 302 and a sacrificial layer 304 are sequentially formed over a substrate 300 by performing a chemical vapor deposition process or a sputtering process, for example. The sacrificial layer 304 is fabricated using a metallic material, for example. It should be noted that the buffer layer 302 is an optional layer mainly serving as a barrier to unexpected dopant diffusion. The presence or absence of the buffer 302 can be determined according to the actual need. In general, there is no particular limitation in this area. The sacrificial layer 304 is, for example, a rectangular film pattern disposed on the buffer layer 302 as shown in FIG. 6A.

The channel region having better electric characteristics of the LTPS-TFT according to the present invention may be manufactured by a process. Detail descriptions of the manufacturing process are described below.

As shown in FIGS. 5B and 6B, a cap layer 306 and an amorphous silicon film 308 are sequentially formed over the buffer layer 302 to cover the sacrificial layer 304. In a subsequent process, the channel layer of the LTPS-TFT is formed within the area 312 above the sacrificial layer 304 and the source/drain region is formed on each side of the area 312. Thus, the width of the sacrificial layer 304 determines the length of the channel layer inside the LTPS-TFT. In other words, length of the channel region within the LTPS-TFT is effectively controlled through the width of the sacrificial layer 304.

As shown in FIG. 5C and 6C, the sacrificial layer 304 is removed to form a gap 310 between the cap layer 306 and the buffer layer 302. The gap 310 encloses some air, for example. The sacrificial layer 304 can be removed by performing a wet etching operation, for example. In other words, the structure as shown in FIG. 5B is immersed in an etching solution (not shown). Since the etching solution has a higher rate for the sacrificial layer 304 relative to other film layers, only the sacrificial layer 304 is removed after the etching operation.

As shown in FIGS. 5D and 5E, a laser annealing process is carried out to melt the amorphous silicon film 308 and permit the melt silicon to re-crystallize into a polysilicon film 308a. Hence, a polysilicon channel layer 522 (the polysilicon film 308a within the area 312) is formed on the cap layer 306 above the gap 310. In the present embodiment, an excimer laser annealing process is used as shown in FIG. 5D. In the annealing process, an excimer laser beam 326 irradiates the amorphous silicon film 308 to convert the silicon material into a liquid state (not shown). After a short period, the liquid state silicon cools down slowly and re-crystallizes into a polysilicon film. Since the area 312 is located above the gap 310 and the gap is filled with air having a coefficient of thermal conductivity ductivity of about 0.025 W/cm²K (much smaller than the coefficient of thermal conductivity of the cap layer 306 and the buffer layer 302), the re-crystallization rate of the liquid silicon within the area 312 is slower than the recrystallization rate at each end of the area 312. In other words, grains grow from each side laterally towards the mid-section of the area 312 to form the polysilicon film 308a during the solidification process. The polysilicon film 308a within the area 312 serves the polysilicon channel 522 of the transistor as shown in FIGS. 5E and 6E.

Since the grains within the area 312 has a slower growth rate, the grain size of grains within the area 312 is on average larger than the grains on each side of the area 312. Therefore, the grains within the polysilicon channel layer 522 have a larger grain size, for example, slightly larger than half the length L of the polysilicon channel layer 522.

In addition, because the total quantity of grain boundary within the polysilicon channel layer 522 is less than the total grain boundary within the area on each side of the channel layer 522, electrons have a higher electron migration rate inside the polysilicon channel layer 522 than elsewhere. Ultimately, the transistor can have a higher electrical performance.

In summary, major advantages of the LTPS-TFT of the present invention includes:

1. Since the grains within the channel region of the transistor has a larger average grain size and a greater uniformity, the transistor of the present invention can have a higher driving current and a higher electron migration rate.

2. The polysilicon film fabricated according to the present invention has a grain orientation parallel to the electron flow direction inside the transistor. Therefore, the electron migration rate within the channel region is increased and electrical performance of the transistor is improved.

3. The width as well as the length of the channel region in the transistor is directly related to the width and length of the sacrificial layer. Hence, the width-to-length ratio of the channel region can be adjusted by controlling the grain size of the sacrificial layer. In other words, the processing window for the LTPS-TFT is increased.

4. The processing equipment for forming the LTPS-TFT according to the present invention is identical to the one used for forming other conventional devices. For example, the conventional equipment for carrying out an excimer laser annealing process can be used to form a polysilicon film with sequential lateral solidification (SLS) quality. That means, aside from improving the final quality of the products, the present invention is able to reduce equipment cost as well.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. A low temperature polysilicon thin film transistor (LTPS-TFT) structure disposed on a substrate, comprising:
a cap layer disposed over the substrate, wherein there is a gap between the cap layer and the substrate;
a polysilicon film disposed over the cap layer, wherein the polysilicon film comprises a channel region and a source/drain region on each side of the channel region, and the channel region is directly above the gap; and
a gate disposed above the channel region of the polysilicon film.

2. The LTPS-TFT structure of claim 1, wherein the structure further comprises a buffer layer sandwiched between the substrate and the cap layer so that the gap is disposed between the cap layer and the buffer layer.

3. The LTPS-TFT structure of claim 2, wherein the gap has a coefficient of thermal conductivity smaller than the coefficient of thermal conductivity of the buffer layer.

4. The LTPS-TFT structure of claim 1, wherein the gap has a coefficient of thermal conductivity smaller than the coefficient of thermal conductivity of the substrate layer.

5. The LTPS-TFT structure of claim 1, wherein the structure further comprises a gate dielectric layer disposed over the polysilicon film.

6. The LTPS-TFT structure of claim 1, wherein the grain size of the channel region of the polysilicon film is on average greater than the grain size of the source/drain region of the polysilicon film.

7. The LTPS-TFT structure of claim 1, wherein the width of the gate is smaller than the average grain size of the channel region.

8. The LTPS-TFT structure of claim 1, wherein the gate comprises a dual gate structure.

9. The LTPS-TFT structure of claim 1, wherein the structure further comprises:
a dielectric layer disposed on the polysilicon film and the gate, wherein the dielectric layer has a plurality of contact windows that exposes the source/drain region of the polysilicon film; and
a source/drain conductive layer disposed on the dielectric layer, wherein the source/drain conductive layer is electrically connected to the polysilicon film in the source/drain region through the contact window.

10-13. (canceled)
